(19) United States
(12) Patent Application Publication
(10) Pub. No.: US 2026/0129916 A1
(43) Pub. Date: May 7, 2026

(54) FLOATING GATE SEPARATING ADJACENT TERMINALS OF CIRCUIT TRANSISTOR

(71) Applicant: Analog Devices, Inc., Wilmington, MA (US)

(72) Inventors: Adalberto Cantoni, Winchester, MA (US); Lawrence A. Singer, Bedford, MA (US)

(21) Appl. No.: 18/936,599

(22) Filed: Nov. 4, 2024

(51) Int. Cl. H01L 29/788; H01L 27/088; H01L 29/417; H01L 29/423; H01L 29/66; H01L 29/78

(52) U.S. Cl. CPC H10D 30/68; H10D 30/024; H10D 30/0411; H10D 30/62; H10D 30/6219; H10D 30/6892; H10D 64/257; H10D 84/834

(57) ABSTRACT

An integrated circuit can include a semiconductor substrate and a field-effect transistor (FET) formed in or on an active area of the substrate. The FET can include a first drain or source region of a specific terminal type, and a second drain or source region of the same terminal type, located adjacent to but physically separated from the first drain or source region. Such regions can be electrically connected via a first electrical conductor path. The FET can include a first floating gate region situated between the first and second drain or source regions. A third drain or source region, of a different terminal type than the first and second regions, is also included and is electrically connected via a second electrical conductor path. A first electrically interconnected gate region can be disposed between the first drain or source region and the third drain or source region.

### BACKGROUND

Field-effect transistors (FETs) are fundamental components in many electronic devices, serving as the building blocks in integrated circuits. FETs can operate by controlling the flow of electrical current within a semiconductor path, such as for amplifying signals or switching electronic signals on and off. The performance of FETs can be significantly influenced by the physical and electrical properties of their constituent materials and the geometric configuration of their source, drain, and gate regions.

### BRIEF DESCRIPTION OF THE DRAWINGS

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

FIG. 1 is a cross-sectional view of an example of a transistor of an integrated circuit (IC), showing a stack of transistor contacts and metal traces.

FIG. 2A is a diagram of an example of a multi-finger transistor including an alternating row of source and drain contacts.

FIG. 2B is a diagram of an example of a multi-finger transistor including multiple successive source or drain contacts in a row of alternating source and drain contacts.

FIG. 2C is a diagram of an example of a multi-finger transistor including floating gates disposed between multiple successive source or drain contacts, within in a row of alternating source and drain contacts.

FIG. 2D is a diagram of an example of a multi-finger transistor including off-biased gates disposed between multiple successive source or drain contacts in a row of alternating source and drain contacts.

FIG. 2E is a schematic diagram showing a resistance between exemplary drain and source contacts and respective capacitances between exemplary a gate and source contact and between a gate and drain contact.

FIG. 2F is a diagram of an example of a multi-finger transistor including floating gates disposed between multiple successive source or drain contacts, within in a row of alternating source and drain contacts.

FIG. 2G is a schematic diagram showing effects of floating gates on a resistance between drain and source contacts and respective capacitances between a gate and source contact and between a gate and drain contact.

FIG. 3A is a diagram of an example of a multi-finger transistor including floating gates disposed between multiple successive source or drain contacts, within in a row of alternating source and drain contacts.

FIG. 3B is a diagram of an example of a multi-finger transistor including floating gates disposed between multiple successive source or drain contacts, within in a row of alternating source and drain contacts.

FIG. 3C is a diagram of an example of a multi-finger transistor including floating gates disposed between multiple successive source, within in a row of alternating source and drain contacts.

FIG. 3D is a diagram of an example of a multi-finger transistor including floating gates disposed between multiple successive source, within in a row of alternating source and drain contacts.

FIG. 3E is a diagram of an example of a multi-finger transistor including floating gates disposed between multiple successive drain contacts, within in a row of alternating source and drain contacts.

FIG. 3F is a diagram of an example of a multi-finger transistor including floating gates disposed between multiple successive drain contacts, within in a row of alternating source and drain contacts.

FIG. 4A is a diagram of an example of a multi-finger transistor including floating gates disposed between multiple successive source or drain contacts, within in a row of alternating source and drain contacts.

FIG. 4B is a diagram of an example of a multi-finger transistor including floating gates disposed between multiple successive source or drain contacts, within in a row of alternating source and drain contacts.

FIG. 4C is a diagram of an example of a multi-finger transistor including floating gates disposed between multiple successive source or drain contacts, within in a row of alternating source and drain contacts.

FIG. 5 is a flowchart showing an exemplary method of making an integrated circuit, including field-effect transistors (FETs) with a floating gate disposed between multiple successive source or drain contacts.

### DETAILED DESCRIPTION

The performance of field-effect transistors (FETs) can be significantly influenced by the physical and electrical properties of their constituent materials and the geometric configuration of their source, drain, and gate regions. It can be desirable in semiconductor fabrication (e.g., during a front end of line (FEOL) or mid end of line (MEOL) process) to scale down certain FET dimensions, such as to develop toward increasing a density and performance of a particular integrated circuit (IC) die or chip. Such scaling, including reducing a feature size of an individual FET, can introduce challenges such as increased parasitic capacitance and resistance, which can adversely affect the speed and efficiency of operating a fabricated transistor.

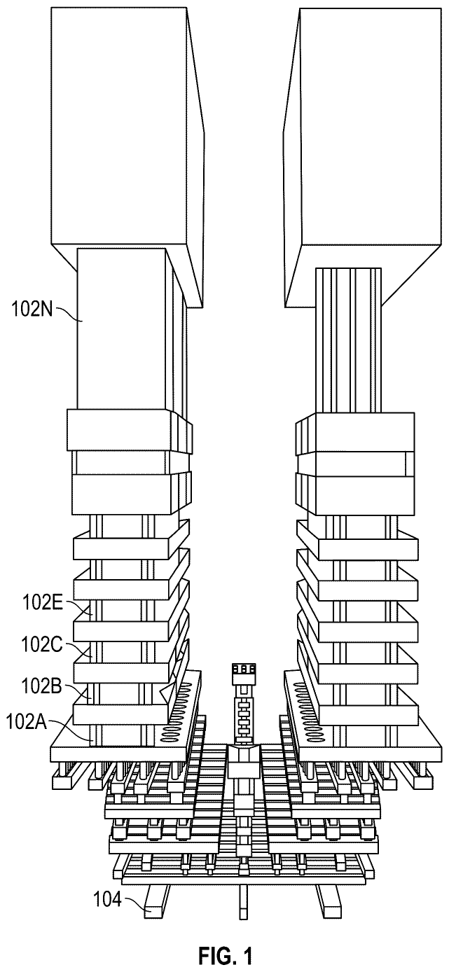

FIG. 1 is a cross-sectional view of an example of a transistor of an integrated circuit (IC), showing a stack of multiple layers of selectively-formed electrically-conductive traces, which can include “vias” between electrically conductive layers from which the electrically conductive traces are formed, transistor contacts to a semiconductor region forming a terminal of the transistor device (e.g., drain, source, gate, body), wherein both “vias” and “contacts” can be referred to in this document generically as “contacts. ” In certain processes, metal contacts 102 can be used to connect elements, such a source or a drain 104, of the IC. As shown in FIG. 1, the metal contacts 102 can include a stack of vias/contacts 102A, 102B, 102C, 102E . . . 102N, each formed of a different metal or metallic compound and collectively establishing a line or trace connection from the transistor to one or more other components of the IC. In an example, the metal contacts 102 can be formed of different metals or metallic compounds such that the different metals progressively (corresponding with 102A, 102B, 102C, 102E . . . 102N) individually exhibit lower resistances, e.g., in a direction away from the substrate, as the semiconductor processing constraints, such as thermal budget, associated with layers that are more distant from the substrate need accommodate less processing heat than layers that are closer to the substrate. But the multi-layer metallization can present a challenge of collectively increasing a resistance between a drain and a source region (R_{ds}), e.g., as metal contacts 102 are progressively added to the stack. Such stacking can also involve a challenge of parasitic resistance, e.g., which can increase in relation to an amount of metal contacts 102 placed in series in the stack, and decreased by increasing the number of metal contacts 102 placed in parallel with each other in a particular layer of the stack. For example, a stacking arrangement can result in a net R_{ds} accumulating to hundreds of ohms for certain connections in the IC, which can have undesired effects on a speed, power consumption, or other performance of the circuit.

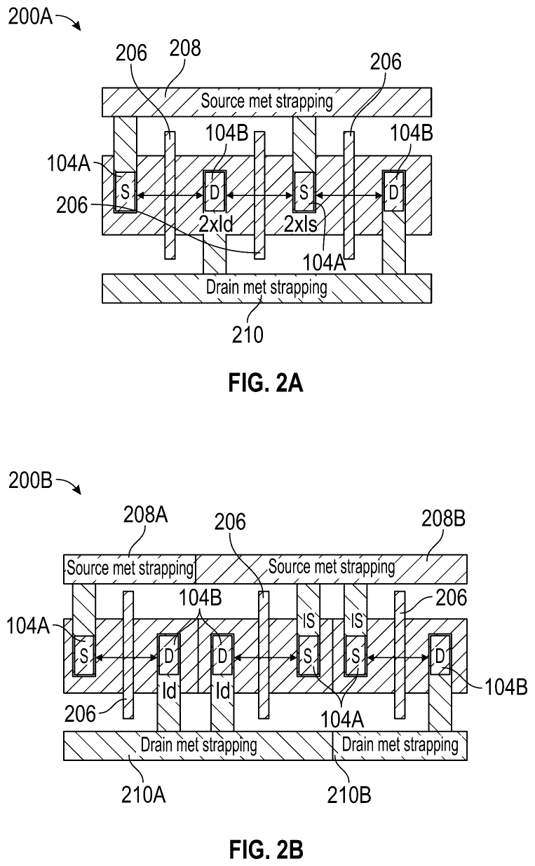

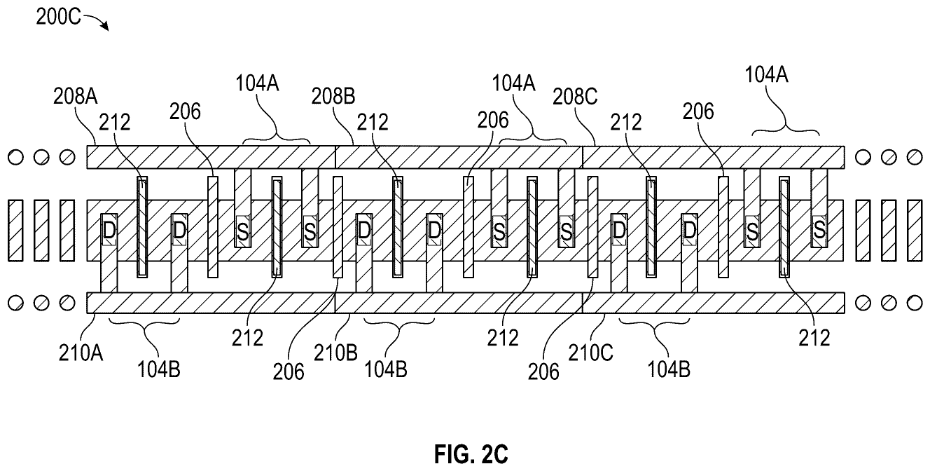

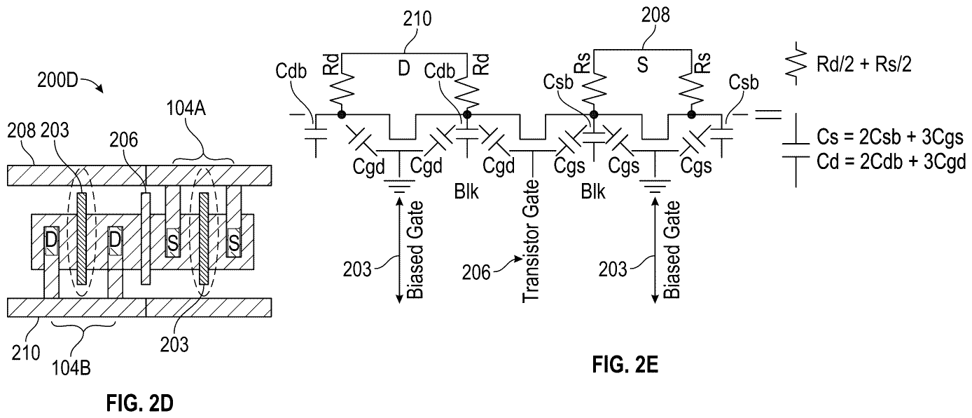

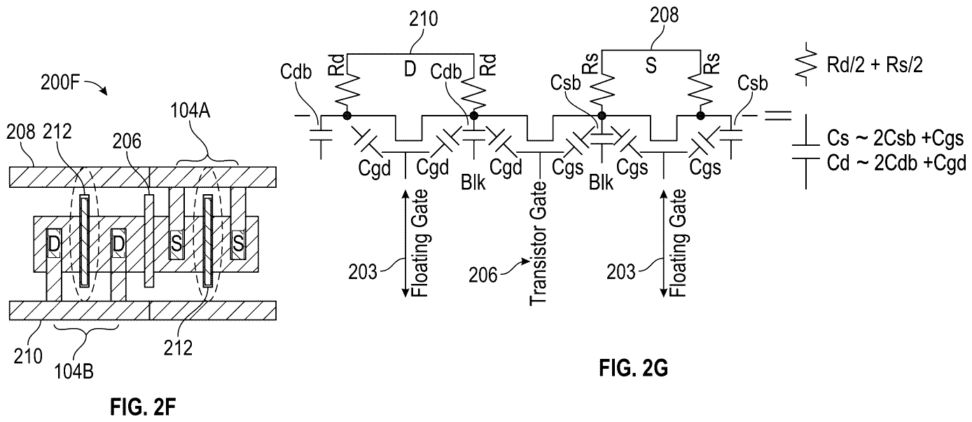

FIG. 2A, FIG. 2B, and FIG. 2C are each top view (looking toward the substrate) diagrams of respective examples of multi-finger transistors. FIG. 2A, FIG. 2B, and FIG. 2C show portion 200A, portion 200B, and portion 200C, respectively, of an alternating row of FET source regions with one or more source contacts 104A and FET drain regions with or more drain contacts 104B. While portion 200A, portion 200B, and portion 200C each depicts a relatively small (e.g., less than 15) number of transistor sources, drains, and contacts, the patterns shown by any of portion 200A, 200B, or 200C can each be repeated along the alternating row, or combined with one another, such as to collectively form a larger sequence of transistors (e.g., repeated to establish dozens, hundreds, thousands, millions, billions, or trillions of field effect transistors (FETs)). Any of portions 200A, 200B, or 200C can be used to form various types of FETs, such as such as FinFETs, planar FETs, gate all around (GAA) FETs, nanowire FETs, or carbon nanotube FETs (CNTFETs). For example, patterning multi-finger transistors, such as displayed in one of FIG. 2A, FIG. 2B, or FIG. 2C, can help form an IC in any technology exhibiting a minimum transistor feature size of equal to or less than about 65 nm, 45 nm, 28 mm, 22 nm, 16 nm, 7 nm, 6 nm, 5 nm, 4 nm, or 3 nm, such as equal to or less than about 55 nm, 32 nm, 20 nm, or 14 nm.

In an example, a plurality of sources or source contacts 104A can be electrically connected to an electrically conductive trace, such as a source metal strapping 208, e.g., in parallel. Similarly, a plurality of drains or drain contacts 104B can be electrically connected to an electrically conductive trace, such as a drain metal strapping 210, e.g., in parallel. A gate region 206 (e.g., a circuit transistor gate) can be disposed between a source contact 104A and a drain contact 104B (such as one electrically interconnected gate region 206 between each source contact 104A and drain contact 104B in the row). The gate region 206 can be electrically interconnected, e.g., via a polysilicon or other electrically conductive trace. When the electrically interconnected gate region 206 is turned on (e.g., is driven via a voltage applied to the gate via the polysilicon trace), current can flow from the source metal strapping 208, to the source region and source contact 104A, through the body region controlled by the electrically interconnected gate region 206, to the drain region and drain contact 104B and to the drain metal strapping 210. Controlling operations of the electrically interconnected gate regions 206 of multi-finger transistors can help to perform various analog or digital operations of the IC, such as logic, arithmetic, memory, latching, software execution, information conversion, data storage, ancillary functionality, etc. The source metal strapping 208 and drain metal strapping 210 may be connected to a biasing signal source (such as a power supply or ground) or other reference or active signal source provided on or off the IC. The source metal strapping 208, the drain metal strapping 210, or the electrically interconnected gate region 206 can be formed using a metal, e.g., Al, Cu, Pd, Pt, Ti, Ag, W, TiN, AlCu, or an alloy including a combination thereof. The semiconductor substrate can be disposed above another layer of semiconductor (e.g., SiGe, SiC, etc.) or other substrate material, such as on top of an insulating layer or on top of a low-permittivity layer. In an example, the source contacts 104A and drain contacts 104B can each comprise registered features that lay atop corresponding semiconductor source or drain regions. For example, the source contacts 104A or drain contacts 104B can be fabricated via a lithography technique, an etching technique, or a combination thereof.

As shown in FIG. 2B, the source contacts 104A or the drain contacts 104B (or both) can be replicated, e.g., doubled, as compared to FIG. 2A, such that the multi-finger transistor comprises an adjacent pair of sources and source contacts 104A or an adjacent pair of drains and drain contacts 104B. For example, the adjacent pair of sources (or likewise the adjacent pair of drains) can extend as fingers approximately parallel to each other and, e.g., approximately perpendicular to a corresponding strapping (e.g., the source metal strapping 208 or the drain metal strapping 210B). Herein, the term “approximately” means marginally varying from an exact direction or dimension due to processing tolerance, e.g., of at most five percent (5%) in one or more permissible dimensions, in at least one dimension, in at least two dimensions, or in at least three dimensions. As discussed earlier with respect to FIG. 1, a resistance of a drain or a source region (R_{ds}) can be an important consideration in determining a physical layout of components (e.g., source 104A, drain 104B, electrically interconnected gate region 206, etc.) of FETs, e.g., in a multi-finger transistor. As compared with the portion 200A of FIG. 2A, the portion 200B of FIG. 2B of an alternating row of pairs of source contacts 104A and pairs of drain contacts 104B can provide an increased area of one or both of the drain 104B and the source 104A. Also, as compared with the portion 200A of FIG. 2A, an individual source contact 104A or drain contact 104B of the portion 200B need handle about half the current applied to the contact, which can help reduce or mitigate an undesired R_{ds}. Where the portion 200B includes an alternating source-drain arrangement including pairs of adjacent sources 104A or pairs of adjacent drains 104B, the portion 200B can exhibit, at certain locations an R_{ds} with a value within a range of about 0.5× and about 0.7× (e.g., at about 0.5×, about 0.55×, about 0.6×, about 0.65×, or about 0.7×) of the R_{ds} of a corresponding single (not paired) feature in portion 200A. Reducing or limiting an R_{ds} (e.g., including reducing a parasitic resistance) via an arrangement of an adjacent pair of sources 104A or an adjacent pair of drains 104B can be beneficial in controlling power consumption, improving performance, etc.

In an example, as shown in FIG. 2C, the source metal strapping 208 can include two or more of a first section of source strapping 208A, second section of source strapping 208B, and a third section of source strapping 208C. Also, the drain metal strapping 210 can include two or more of a first section of drain strapping 210A, a second section of drain strapping 210B, and a third section of drain strapping 210C. In an example, the first source strapping 208A can be electrically isolated from one or both of the second source strapping 208B or the third source strapping 208C. Also, one or both of the first drain strapping 210A or the second drain strapping 210B can be electrically isolated from the third drain strapping 210C to form different circuits. Such a formation of different circuits can be advantageous, e.g., in that it can exhibit less parasitic capacitance or less parasitic resistance than a comparable multi-fingered, single transistor. FIG. 2D is a diagram of an example of a multi-finger transistor including multiple successive source or drain contacts in a row of alternating source and drain contacts. FIG. 2E is a schematic diagram of an example of a multi-finger transistor. In an example, as compared to a transistor of the portion 100 200A, the adjacent pair of sources 104A and the adjacent pair of drains 104B of a portion 200D can result in an R_{ds} of about 0.5× as compared with the R_{ds} of a transistor of the portion 200A of FIG. 2A. A challenge to “doubling” sources 104A or drains 104B, as depicted in FIG. 2D, is that such an arrangement can exhibit a capacitance of the source (Cₛ) or a capacitance of the drain (C_{d}) of about 2× or >2× as compared with the corresponding Cₛ or C_{d} of the portion 200A of FIG. 2A. For example, certain techniques involving doubling sources 104A or drains 104B can help to reduce or mitigate an R_{ds}, at the expense of increasing a Cₛ or C_{d} (e.g., including introducing additional (e.g., up to 3× as compared to portion 200A) a parasitic capacitance between the gate and the source (C_{gs}) or between the gate and the drain (C_{gd}) via adjacent pairs of sources 104A or drains 104B). For example, such an increase in C_{gs} or C_{gd} can relate to an inclusion of a biased gate 203 arranged between adjacent drains 104B or arranged between adjacent sources 104A. A similar increase in Cₛ or C_{d}, as compared to portion 200A of FIG. 2A, can be observed where no gate is present between adjacent pairs of sources 104A or between adjacent pairs of drains 104B (such as depicted in FIG. 2B). Significantly increasing (at, near, or greater than 2×) of the Cₛ or C_{d} can introduce certain challenges in an integrated circuit (IC), such as such as in terms of increased signal delay, distortion or attenuation, power consumption, or may limit termination or other design options, etc. The present inventors have recognized an importance of arranging source and drain contacts (e.g., doubling sources 104A or drains 104B) of a multi-finger transistor to reduce or limit an R_{ds} while also limiting a Cₛ or C_{d}, which could otherwise be increased by certain approaches of the doubling sources 104A or drains 104B.

FIG. 2C and FIG. 2F each depict a diagram of an example of a multi-finger transistor including “floating” (e.g., electrically unconnected) gates disposed between multiple successive source or drain contacts, within in a row of alternating source and drain contacts. In the context of this document, such “floating” gates can be contrasted with—and distinguished from—a floating gate of an EEPROM or similar memory device in that, in the present context, there need not be any control gate in proximity to the floating gate from which to control charge tunneling through a gate insulator to store a charge on the floating gate for use as a storage device. In an example, the portion 200C can include an adjacent pair of sources 104A or an adjacent pair of drains 104B, similar to that described above with respect to the portion 200B and FIG. 2B and also similar to that described with respect to the portion 200D in FIG. 2D. As shown in FIG. 2F, the portion 200F can include a floating gate region 212 disposed between an adjacent pair of sources 104A or disposed between an adjacent pair of drains 104B. In an example, the floating gate region 212 can be electrically unbiased, e.g., not electrically connected to be controlled via an external source of power or bias or connected to a known potential or ground. For example, the floating gate region 212 can omit gate contacts or can be left electrically unconnected by any interconnect to any electrical bias or other driven electrical signal. As discussed below with respect to FIG. 2E, an inclusion of a floating gate region 212 between the adjacent pair of sources 104A or the adjacent pair of drains 104B can help mitigate or avoid a parasitic capacitance attributable to the arrangement of an adjacent pair of sources 104A or an adjacent pair of drains 104B (i.e., “doubling”) along a multi-finger transistor. Also, the absence of a bias on the floating gate region 212 can help simplify and interconnect at or near the gate structure and can help reduce a complexity of the transistor's control mechanisms as compared to other approaches, e.g., including a biased gate between doubled source or drain regions 104 of a multi-finger transistor.

In an example, the floating gate region 212 can be formed of a material such as polysilicon, indium-tin-oxide, aluminum, or silver, carbon nanotubes (CNTs), or a combination thereof. In an example, the floating gate region 212 can have a dimension between about 1 nanometer (nm) and about 100 nm, such as between about 1.5 nm and about 2.5 nm, such as a gate length of about 2 nm, 6 nm, or 86 nm. In an example, a pitch between floating gate regions 212 (e.g., a distance from one floating gate region 212 and the next adjacent floating gate region 212 along the multi-finger transistor) can be within a range of about 50 nm and about 500 microns. In an example, a gate-to-gate pitch can vary, within a same tech node, such as based on or corresponding with the respective gate length utilized in the multi-finger array. Likewise, a pitch between electrically interconnected gate regions 206 (e.g., a distance from one electrically interconnected gate region 206 and the next adjacent electrically interconnected gate region 206 along the multi-finger transistor) can be within a range of about 5 nm and about 500 microns. In an example, a pitch between floating gate regions 212 (e.g., a distance from one floating gate region 212 and the next adjacent floating gate region 212 along the multi-finger transistor) can be within a range of about 1 times (1×) to about 5 times (5×) a specified integrated circuit manufacturing process minimum gate-to-gate pitch parameter, e.g., corresponding with a specified gate length, such as within a range of about 1.5 times (1.5×) to about 5 times (5×) the specified process minimum gate-to-gate pitch parameter or within a range of about 1 times (1×) to about 2.5 times (2.5×) the specified process minimum gate-to-gate pitch parameter.

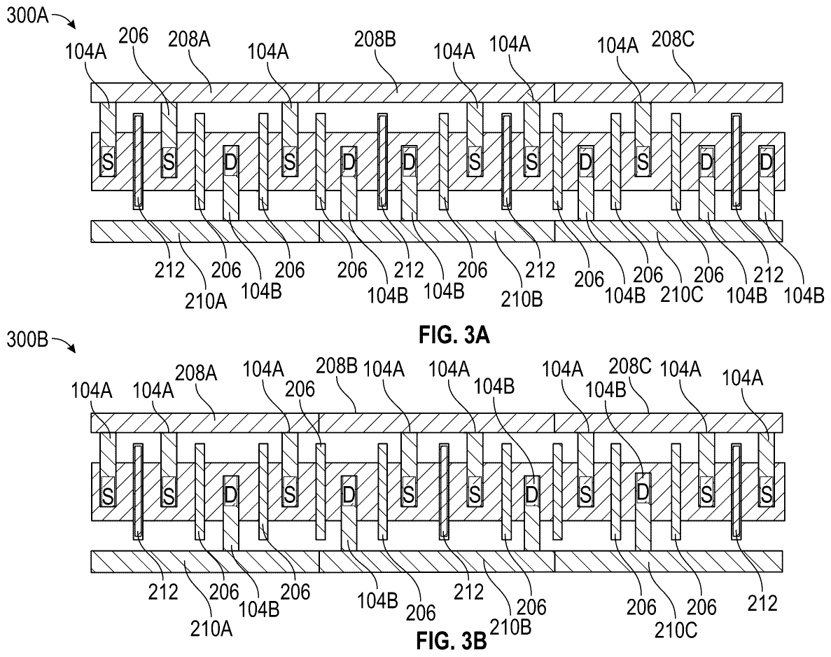

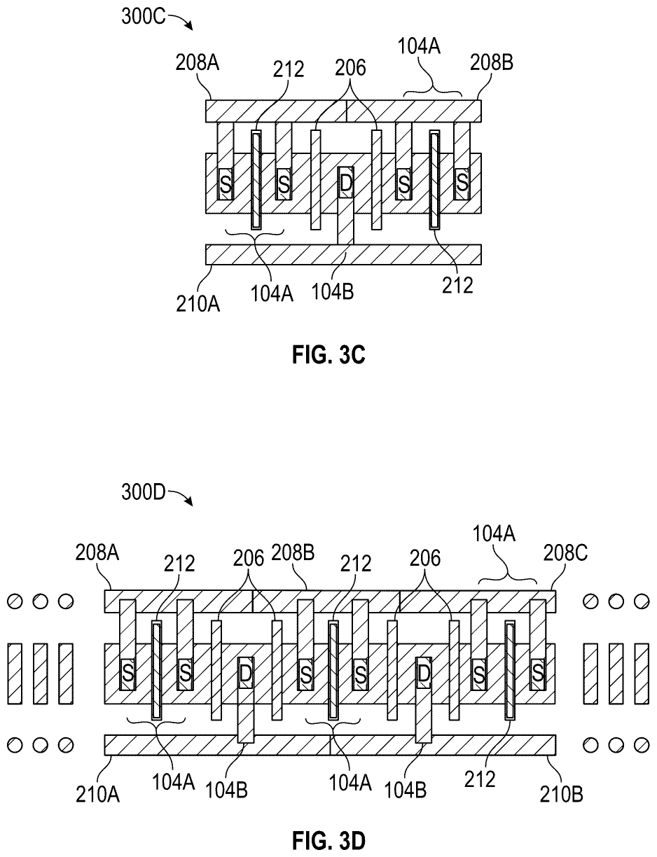

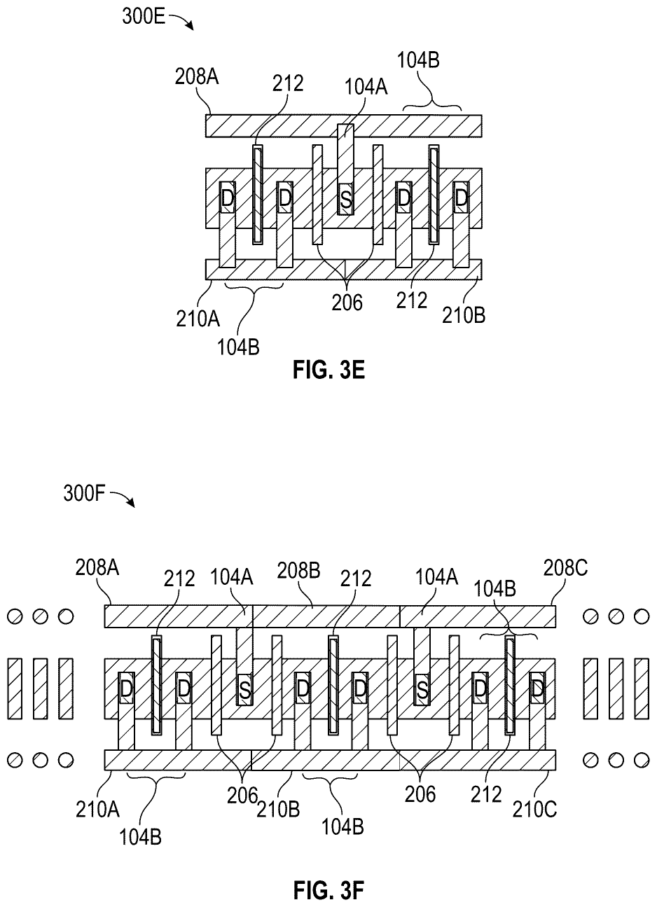

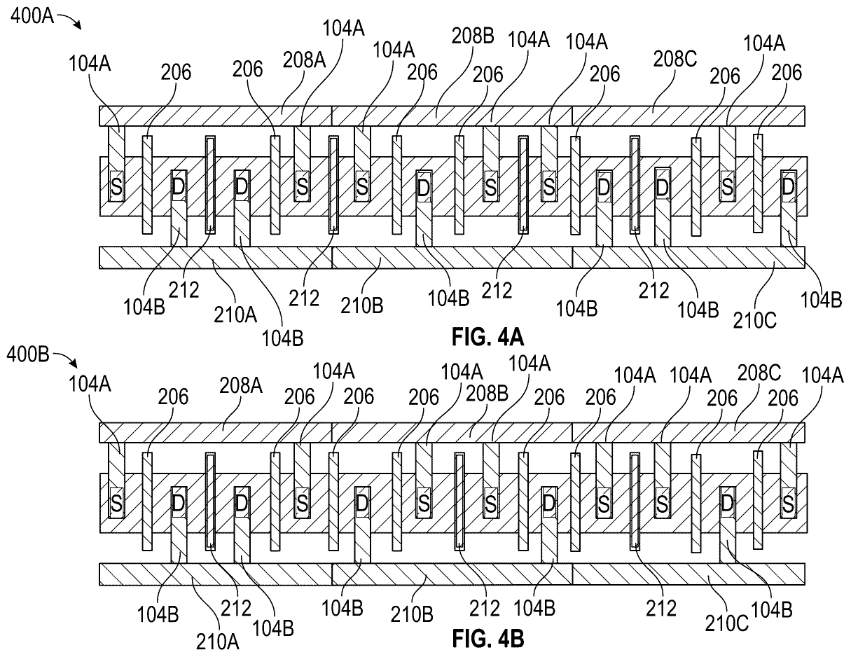

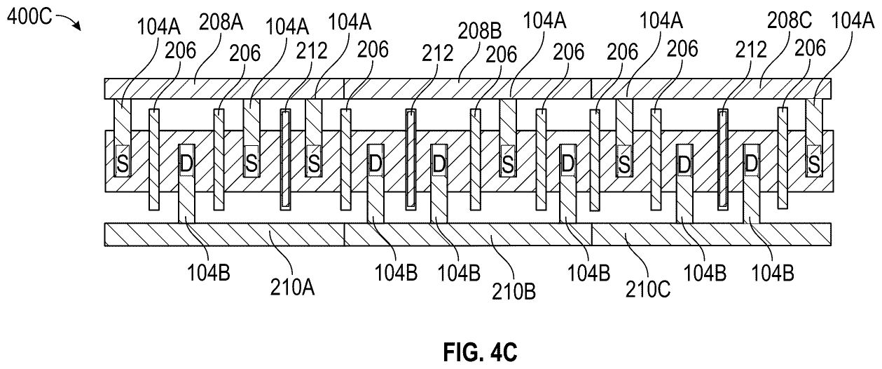

FIG. 2G is a schematic diagram that corresponds with the portion 200F of FIG. 2F. In an example, as compared to a transistor of the portion 200A, the adjacent pair of sources 104A and the adjacent pair of drains 104 of the portion 200C can result in an R_{ds} of about 0.5× as compared with the R_{ds} of a transistor of the portion 200A of FIG. 2A. The arrangement of the floating gate regions 212 can help mitigate the challenge of “doubling” sources 104A or drains 104B, is that such an arrangement can exhibit a capacitance of the source (Cₛ) (e.g., C_{gs}) or a capacitance of the drain (C_{d}) (e.g., C_{gd}) of less than 2× as compared with the Cₛ or C_{d} as compared to the portion 200A of FIG. 2A and also less than Cₛ or C_{d} exhibited if the floating gates regions were biased, as shown in FIG. 2D and the schematic of FIG. 2E. For example, C_{gs} or C_{gd} can be less than about 2×, of the corresponding C_{gs} or C_{gd} of the portion 200D, as depicted in FIG. 2D. Such an avoidance (related to the floating gate region 212) of increased Cₛ or C_{d} (related to a reduction of the R_{ds} related to the doubling sources 104A or drains 104B) can help improve an operation of the integrated circuit (IC), such as such in avoiding or mitigating undesired signal delay, distortion or attenuation, or power consumption. As in the various examples of multi-finger transistor portion 300A in FIG. 3A, portion 300B in FIG. 3B, portion 300C in FIG. 3C, portion 300D in FIG. 3D, portion 300E in FIG. 3E, portion 300F in FIG. 3F, portion 400A in FIG. 4A, portion 400B in FIG. 4B, and portion 400C in FIG. 4C, various combinations, subcombinations, or permutations of the multi-finger arrangements shown in the portion 200A and the portion 200C (as depicted in FIG. 2A and FIG. 2C, respectively) can be arranged in sequence such as to balance a “trade-off” of parasitic capacitance of a multi-finger transistor with a parasitic resistance of the multi-finger transistor, e.g., via selecting a placement of adjacent sources 104A or drains 104B (and floating gate regions 212 therebetween) along a row of FETs in an integrated circuit. In an example, any subportion (such as defined along an individual strapping section 208A/210A, 208B/210B, or 208C/210C), of any of portion 300A, portion 300B, portion 300C, portion 300D, portion 300E, portion 300F, portion 400A, portion 400B, or portion 400B can be combined with each other to form other permutations. The patterns shown by any of portions 300A, 300B, 300C, 300D, 300E, 300F, 400A, 400B, 400C or any subportions thereof can each be repeated along an alternating row, or combined with one another, such as to collectively form a larger sequence of transistors (e.g., repeated to establish dozens, hundreds, thousands, millions, billions, or trillions of field effect transistors (FETs)). Any of 300A, 300B, 300C, 300D, 300E, 300F, 400A, 400B, 400C or any subportions thereof can be used to form various types of FETs, such as such as FinFETs, planar FETs, gate all around (GAA) FETs, nanowire FETs, or carbon nanotube FETs (CNTFETs). For example, patterning multi-finger transistors such as displayed in one of FIG. 3A, FIG. 3B, FIG. 3C, FIG. 3D, FIG. 3E, FIG. 3F, FIG. 4A, FIG. 4B, or FIG. 4C, can help form an IC in any technology exhibiting a minimum transistor feature sizes of equal to or less than about 5 nm, 45 nm, 32 nm, 28 nm, 22 nm, 16 nm, 7 nm, 6 nm, 5 nm, 4 nm, or 3 nm, such as about 55 nm, 32 nm, 20 nm, or 14 nm

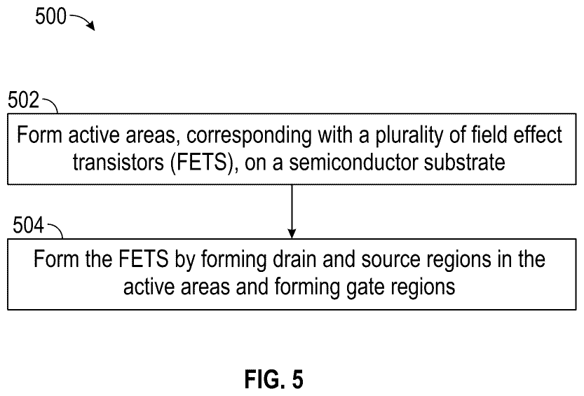

FIG. 5 is a flowchart describing a process manufacturing an integrated circuit. For example, the process can be used to manufacture 200A, 200B, 200C, 200D, 200F, 300A, 300B, 300C, 300D, 300E, 300F, 400A, 400B, 400C, (depicted in FIG. 2A, FIG. 2B, FIG. 2C, FIG. 2D, FIG. 2F, FIG. 3A, FIG. 3B, FIG. 3C, FIG. 3D, FIG. 3E, FIG. 3F, FIG. 4A, FIG. 4B, FIG. 4C) any subportions thereof, or a combination thereof. For example, the process can be carried out via a fabricating mechanism as part of an integrated circuit fabrication process, or a specific semiconductor manufacturing provider.

At 502, the process 500 can include forming active areas, corresponding with a plurality of field effect transistors (FETs), on a semiconductor substrate of the integrated circuit. For example, the FETs can eventually comprise arrangements such as FinFETs, planar FETs, gate all around (GAA) FETs, nanowire FETs, or carbon nanotube FETs (CNTFETs).

At 504, the process 500 can include forming the FETs, e.g., by forming drain and source regions in the active areas and forming gate regions. For example, the process 500 can include forming a first drain or source region, being one of a drain terminal type or a source terminal type. The process can also include forming a second drain or source region, of the same terminal type as the first drain or source region, adjacent to but physically separated from the first drain or source region, the second drain or source region electrically connected to the first drain or source region via a first electrical conductor path. Here, the process 500 can include disposing a first floating gate region between the first drain or source region and the second drain or source region. The process 500 can include forming a third drain or source region, of a different terminal type than the first and second drain or source regions. For example, the third drain or source region can be electrically connected via a second electrical conductor path. The process 500 can also include disposing a first electrically interconnected gate region between the first drain or source region and the third drain or source region.

In an example, the process 500 can include forming a fourth drain or source region of the same terminal type as the third drain or source region in the active areas. The fourth drain or source region can be adjacent to but physically separated from the third drain or source region, and e.g., can be electrically connected via the second electrical conductor path. Here, a second floating gate region can be disposed between the third and fourth drain or source regions. The floating gate regions can be formed of materials such as polysilicon, indium-tin-oxide, aluminum, or silver, carbon nanotubes (CNTs), or a combination thereof.

The process 500 can also include forming n-type or p-type FETs. In an example, e.g., once the regions, paths, and configurations are established, the FETs can undergo a finalization protocol such as involving rigorous testing to ensure they meet certain specifications and performance criteria.

The above Detailed Description can include references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the inventors also contemplate examples in which only those elements shown or described are provided. Moreover, the inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that can include elements in addition to those listed after such a term in a claim are still deemed to fall within the scope of that claim.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In this document, the terms “including” and “in which” are used as the plain-English equivalents of the respective terms “comprising” and “wherein. ” Also, in the following claims, the terms “including” and “comprising” are open-ended, that is, a system, device, article, composition, formulation, or process that can include elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An integrated circuit comprising:
a semiconductor substrate; and
a field-effect transistor (FET), formed in or on an active area of the substrate, the field-effect transistor comprising:
a first drain or source region, being one of a drain terminal type or a source terminal type;
a second drain or source region, of the same terminal type as the first drain or source region, located adjacent to but physically separated from the first drain or source region, the second drain or source region electrically connected to the first drain or source region via a first electrical conductor path;
a first floating gate region, located between the first drain or source region and the second drain or source region;
a third drain or source region, of a different terminal type than the first and second drain or source regions, the third drain or source region electrically connected via a second electrical conductor path; and
a first electrically interconnected gate region located between the first drain or source region and the third drain or source region.

2. The integrated circuit of claim 1, further comprising:
a fourth drain or source region, of the same terminal type as the third drain or source region, located adjacent to but physically separated from the third drain or source region, the fourth drain or source region electrically connected to the third drain or source region, via the second electrical conductor path; and
a second floating gate region, located between the third drain or source region and the fourth drain or source region.

3. The integrated circuit of claim 1, comprising:
a second electrically interconnected gate region;
wherein:
the first floating gate region is located between the first electrically interconnected gate region and the second electrically interconnected gate region; and
a distance between the first electrically interconnected gate region and the second electrically interconnected gate region is within a range of 1.5 times and 5 times a specified integrated circuit manufacturing process minimum gate-to-gate pitch parameter.

4. The integrated circuit of claim 3, wherein a distance between the first floating gate region and each of the first and second electrically interconnected gate regions is within a range of 1 times to 2.5 times a specified integrated circuit manufacturing process minimum gate-to-gate pitch parameter.

5. The integrated circuit of claim 1, wherein the first floating gate is electrically unbiased by electrical charge tunneled and stored onto the first floating gate.

6. The integrated circuit of claim 1, wherein the first floating gate is not accessible by any control gate.

7. The integrated circuit of claim 1, wherein the first floating gate region is formed of a material including polysilicon.

8. The integrated circuit of claim 1, wherein the FET includes a FinFET.

9. The integrated circuit of claim 1, further comprising:
a fourth drain or source region, of the same terminal type as the first and second drain or source regions, physically separated from the third drain or source region, and electrically connected to the first and second drain or source regions; and
a second electrically interconnected gate region located between the third drain or source region and the fourth drain or source region.

10. The integrated circuit of claim 9, further comprising:
a fifth drain or source region, of the same terminal type as the fourth drain or source region, located adjacent to but physically separated from the fourth drain or source region, the fifth drain or source region electrically connected to the fourth drain or source region; and
a second floating gate region, located between the fourth drain or source region and the fifth drain or source region.

11. An integrated circuit comprising:
a semiconductor substrate; and
a plurality of field-effect transistors (FETs), formed in or on an active area of the substrate, an individual FET comprising:
a first drain or source region, being one of a drain terminal type or a source terminal type;
a second drain or source region, of the same terminal type as the first drain or source region, located adjacent to but physically separated from the first drain or source region, the second drain or source region electrically connected to the first drain or source region via a first electrical conductor path;
a first floating gate region, located between the first drain or source region and the second drain or source region;
a third drain or source region, of a different terminal type than the first and second drain or source regions, the third drain or source region electrically connected via a second electrical conductor path; and
a first electrically interconnected gate region located between the first drain or source region and the third drain or source region;
wherein the plurality of FETs are arranged in or on the substrate as an at least one-dimensional array of transistors.

12. The integrated circuit of claim 11, further comprising:
a fourth drain or source region, of the same terminal type as the third drain or source region, located adjacent to but physically separated from the third drain or source region, the fourth drain or source region electrically connected to the third drain or source region, via the second electrical conductor path; and
a second floating gate region, located between the third drain or source region and the fourth drain or source region.

13. The integrated circuit of claim 11, comprising:
a second electrically interconnected gate region;
wherein:
the first floating gate region is located between the first electrically interconnected gate region and the second electrically interconnected gate region; and
a distance between the first electrically interconnected gate region and the second electrically interconnected gate region is within a range of 1.5 times and 5 times a specified integrated circuit manufacturing process minimum gate-to-gate pitch parameter.

14. The integrated circuit of claim 13, wherein a distance between the first floating gate region and each of the first and second electrically interconnected gate regions within a range of 1 times to 2.5 times a specified integrated circuit manufacturing process minimum gate-to-gate pitch parameter.

15. The integrated circuit of claim 11, wherein:
the first and second drain or source regions extend as fingers parallel to each other and are electrically interconnected to each other via first electrical conductor path; and
the third drain or source region extends parallel to the first and second drain or source regions and are electrically interconnected to each other via the second electrical conductor path.

16. The integrated circuit of claim 11, wherein the first floating gate is electrically unbiased by electrical charge tunneled and stored onto the first floating gate.

17. A method of manufacturing an integrated circuit, the method comprising:
forming active areas, corresponding with a plurality of field effect transistors (FETs), on a semiconductor substrate of the integrated circuit; and
forming the FETs by forming drain and source regions in the active areas and forming gate regions, including, for an individual FET:
forming a first drain or source region, being one of a drain terminal type or a source terminal type;
forming a second drain or source region, of the same terminal type as the first drain or source region, located adjacent to but physically separated from the first drain or source region, the second drain or source region electrically connected to the first drain or source region via a first electrical conductor path;
disposing a first floating gate region between the first drain or source region and the second drain or source region;
forming a third drain or source region, of a different terminal type than the first and second drain or source regions, the third drain or source region electrically connected via a second electrical conductor path; and
disposing a first electrically interconnected gate region between the first drain or source region and the third drain or source region.

18. The method of claim 17, wherein the forming the FETs includes:
forming n-type FETs;
forming alternatingly arranged n-type circuit FETs and n-type floating FETs.

19. The method of claim 17, wherein the forming the FETs includes:
forming p-type FETs;
forming alternatingly arranged p-type circuit FETs and p-type floating FETs.
